(19) United States
(12) Patent Application Publication
(10) Pub. No.: US 2020/0216690 A1
(43) Pub. Date: Jul. 9, 2020

(54) INK JET RESIN COMPOSITION AND PRINTED WIRING BOARD USING THE SAME

(71) Applicant: MICROCRAFT KOREA CO., LTD., Gyeonggi-do (KR)

(72) Inventors: Yorio Hidehira, Okayama (JP); Sung Ho Choi, Gyeonggi-do (KR); Dong Heun Shin, Incheon (KR)

(73) Assignee: MICROCRAFT KOREA CO., LTD., Gyeonggi-do (KR)

(21) Appl. No.: 16/301,761

(22) PCT Filed: May 16, 2017
(86) PCT No.: PCT/KR2017/005068

§ 371 Date: Nov. 15, 2018

(30) Foreign Application Priority Data
May 17, 2016 (KR) 10-2016-0060115

(51) Int. Cl. C09D 11/101; B41M 5/00; B41M 7/00; C09D 11/322; C09D 11/102; C09D 11/38; H05K 3/28

(52) U.S. Cl. CPC C09D 11/101; B41M 5/0047; B41M 7/0081; B41M 7/009; H05K 2203/013; C09D 11/322; C09D 11/102; C09D 11/38; H05K 3/287; B41M 5/0023

(57) ABSTRACT

The present invention provides an ink jet composition including a thermosetting epoxy resin, a monofunctional acrylate monomer, a polyfunctional acrylate monomer, a photoinitiator, and an amine synergist. The ink jet resin composition according to the present invention may improve heat resistance, chemical resistance and adhesion of a cured resin layer obtained by curing the composition. In particular, in contrast to the conventional ink jet resin composition, the resin composition may be easily discharged (jetted) from an ink jet printer without using a solvent but even when using a diluent, thereby forming a resin insulating layer without influencing the characteristics of a printed wiring board.

### FIELD OF THE INVENTION

The present invention relates to an ink jet resin composition and a printed wiring board using the same.

### DESCRIPTION OF THE RELATED ART

Recently, as a method for protecting a conductor circuit formed on a wiring board such as a printed wiring board, methods for forming a cured insulating layer on a printed wiring board using a resin composition such as a solder resist by using an ink jet printer are being diversely studied (Patent Document 1).

In the conventional methods, the resin composition was applied on a substrate by a screen printing method, a spray method, a curtain method, a dip coater method, a dry film method, etc., but these are all photo developing type methods which require complicated processes from printing or laminating at the onset to processes such as drying, exposing, developing, final curing and final UV curing.

When a cured layer is formed by an ink jet method, a process may be completed by printing via an ink jet and then performing final curing. Such an ink jet method may have advantages in not generating contaminating materials during an exposing process and a wet process such as a developing process.

However, in order to use the ink jet method, a resin composition used as ink is required to satisfy the physical properties of low viscosity, excellent pigment dispersibility, and storage stability, and at the same time, to have insulation reliability, surface strength, etc., which are required for conventional solder resist materials.

### PRIOR ART DOCUMENT

### Patent Document

Japanese Patent Laid-open No. Hei7-263845

### SUMMARY OF THE INVENTION

### The Problem to be Solved

The task to be solved by the present invention is to provide a resin composition that may be used in an ink jet method.

### Means for Solving the Problem

In order to solve the above-described task, an aspect of the present invention provides an ink jet resin composition including a thermosetting epoxy resin, a monofunctional acrylate monomer, a polyfunctional acrylate monomer, a photoinitiator, and an amine synergist.

### Advantageous Effect

The ink jet resin composition according to the present invention may improve the heat resistance, chemical resistance and adhesion of a cured resin layer obtained by curing the composition. In particular, in contrast to the conventional ink jet resin composition, a resin composition may be easily discharged (jetted) from an ink jet printer even when using a diluent instead of a volatile solvent, so as to be capable of forming a resin insulating layer without influencing the characteristics of a printed wiring board.

### BRIEF DESCRIPTION OF THE DRAWINGS

FIGS. 1 and 2 are photographic surface images of a sample for assessment according to Example 5; and

FIGS. 3 and 4 are photographic surface images of a sample for assessment according to Comparative Example 11.

### DETAILED DESCRIPTION OF THE PREFERRED EMBODIMENT

Hereinafter, preferred embodiments of the present invention will be explained in detail. It will be understood that words or terms used in the specification and claims shall not be interpreted as the meaning defined in commonly used dictionaries. It will be further understood that the words or terms should be interpreted as having a meaning that is consistent with their meaning in the context of the relevant art and the technical idea of the invention, based on the principle that an inventor may properly define the meaning of the words or terms to best explain the invention.

Accordingly, since the configuration of embodiments set forth in the present specification are shown by way of a preferred embodiment and do not represent all the technological spirit of the present invention, it should be understood that embodiments of the present invention may include various equivalents and alternatives at the time of the present application.

In order to satisfy the above-described requirements, an embodiment of the present invention provides an ink jet resin composition including a thermosetting epoxy resin, a monofunctional acrylate monomer, a polyfunctional acrylate monomer, a photoinitiator, and an amine synergist.

The epoxy resin may have an epoxy equivalent weight (EEW) of 200 g/eq to 600 g/eq, or a weight average molecular weight of 1,000 to 5,000. If the epoxy equivalent weight is less than 100 g/eq, adhesion to a copper foil and heat resistance are not good, and if the epoxy equivalent weight is greater than 600 g/eq, storage stability is not good. If the weight average molecular weight is less than 1,000, adhesion to a copper foil and heat resistance are not good, and if the weight average molecular weight is greater than 5,000, discharging properties (Jeting Stability) from an ink jet head are not good due to high viscosity.

Conventionally, a resin having a low viscosity was used for easy discharging (jetting) of a composition from an ink jet head, but according to an embodiment of the present invention, even when an epoxy resin having high epoxy equivalent weight or high molecular weight is used, an ink jet resin composition may have a viscosity which enables easy discharging (jetting) from an ink jet head. Hereinafter, the viscosity indicates a measured viscosity according to JIS K2283.

Non-limiting examples of the epoxy resin may include at least one selected from the group consisting of a bisphenol A-type epoxy resin, a bisphenol F-type epoxy resin, a cresol novolak epoxy resin, a phenol novolak epoxy resin, halogen substituted products of the resins, alkynol substituted products of the resins, and hydrogenation products of the resins.

The resin composition according to an embodiment of the present invention may include a monofunctional acrylate monomer as a diluent without adding a separate solvent to the thermosetting epoxy resin to secure a predetermined viscosity for discharging (jetting) from the ink jet.

In particular, the monofunctional acrylate monomer may include at least one selected from the group consisting of isobornyl acrylate (IBOA), acryloyl morpholine (ACMO), trimethylolpropane formal acrylate (CTFA), and 2-phenoxyethyl acrylate (2PEA).

As the diluent, at least one of dipropylene glycol diacrylate (DPGDA) or 1,6-hexanediol diacrylate (HDDA) may be further included as a bifunctional acrylate monomer in the resin composition.

The monofunctional acrylate monomer or the bifunctional acrylate monomer as the diluent may use a monofunctional acrylate monomer or a bifunctional acrylate monomer having a molecular weight of 10 to 1,000 and a viscosity of 1 to 50 cps (room temperature) in order to dilute the thermosetting epoxy resin. If the viscosity of the monofunctional acrylate monomer or the bifunctional acrylate monomer is 50 cps or more, the final viscosity as a resin composition ink used in an ink jet may increase, making the ink difficult to use. In addition, if the molecular weight increases, solubility may be decreased. Tg of the monofunctional acrylate monomer or the bifunctional acrylate monomer may be at least 10° C. to 100° C. If the Tg is less than 10° C., heat resistance and chemical resistance required as a solder resist material may be weak, and if the Tg is greater than 100° C., the solubility with respect to the thermosetting epoxy resin may be decreased.

In order to increase the curing rate and the viscosity control of a resin composition in which the thermosetting epoxy resin and the monofunctional acrylate monomer are added as diluents, a polyfunctional acrylate monomer may be included as a viscosity controlling agent to the resin composition.

Particular examples of the polyfunctional acrylate monomer may be at least one selected from the group consisting of dipentaerythritol hexaacrylate (DPHA), pentaerythritol triacrylate (PETA), pentaerythritol tetraacrylate (PETRA), ditrimethylolpropane tetraacrylate (DiTMPTA), polyether tetraacrylate, polyester tetraacrylate, trimethylolpropane triacrylate (TMPTA), and tricyclodecane dimethanol diacrylate (TCDDA).

The ink jet resin composition according to the present invention may be UV cured for pre-curing during discharging (jetting) of the resin composition from an ink jet head as described above. In order to perform a UV curing reaction, a photoinitiator may be included in the resin composition.

In particular, the photoinitiator may include at least one selected from the group consisting of an α-hydroxyketone-based compound, a benzyldimethyl-ketal-based compound, an α-aminoketone-based compound, a bis-acyl phosphine-based (BAPO) compound, and a mono acyl phosphine-based compound.

The photoinitiator may produce radicals in the resin composition by UV rays and may make contact with oxygen in the air to produce peroxides. When the resin composition is discharged (jetted) from the ink jet head and makes contact as droplets with a wiring board, the epoxy resin may be partially cured in the air.

However, in the case where the resin composition is exposed to oxygen in the air, oxygen present in the air may retard the UVW curing reaction in another aspect, and thus, the curing of the epoxy resin(The reaction of photo-curing) may be restrained (hindered). In order to secure the physical properties of a cured resin layer formed after thermal curing which is performed after the UV curing, and in an aspect of the developing properties of the resin composition discharged (jetted) from the ink jet head, an appropriate performance of UV curing is significant. In this regard, an amine synergist may be included in the ink jet resin composition to prevent the restraint of the UV curing due to oxygen hindrance according to an embodiment of the present invention.

The amine synergist may be included in the composition and may play the role of collecting (Trapping) oxygen in the air to minimize the above-described oxygen hindrance (inhibition) phenomenon. Diligent research by the present inventors shows that when the amine synergist is used together, radicals of the amine synergist may be produced in addition to the radicals of the photoinitiator during UVW curing, and the radicals may react with oxygen to produce peroxides. From this phenomenon, the restraint of UVW curing due to oxygen may be further minimized. Further, the amine synergist peroxides may be easily decomposed like the photoinitiator during the thermal curing of the epoxy resin which is performed after the UVW curing, and an easier polymerization initiation reaction may be promoted.

The amine synergist may be an acrylate including two to five tertiary amine structures as functional groups in a molecule for the oxygen collection and easy production of radicals by UV rays. In particular, the amine synergist may use at least one selected from the group consisting of a compound represented by the following Formula 1, MIRAMER AS2010 (Miwon Commercial Co., Ltd.), bis-N,N-[(4-dimethylaminobenzoyl) oxiethylen-1-yl]-methylamine, and MIRAMER AS5142 (Miwon Commercial Co., Ltd.) or derivative thereof:

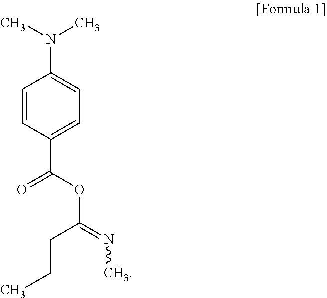

The resin composition according to an embodiment of the present invention may selectively further include a photo auxiliary agent (photosensitizers). The photo auxiliary agent may include at least one of a phosphine oxide-based compound or a thioxanthone-based compound.

The solder resist for a printed board of the present invention has color, and generally, the color of a substrate in this technical field is green. Accordingly, the resin composition as a solder resist may further include a pigment.

Physical properties required for the pigment may include clear color, hiding power of a base substrate having low transparency, and dispersion stability. Green pigments may include organic pigments including halogen compounds of Cl, Br, etc., and inorganic pigments including heavy metals, which may induce environmental problems such as not being halogen-free or meeting RoHAS regulations.

In this case, a blue pigment and a yellow pigment may be used in combination. However, in the case where green is attained by combining two or more colors, and using only inorganic pigments, a color with deteriorated color clarity such as pastel green may be attained, but the hiding power of a base substrate may be excellent, and dispersion stability may be good. In addition, if only organic pigments are combined, color clarity and dispersion stability may be good, but hiding power may be deteriorated due to transparency according to a low refractive index.

In order to solve the above-described tasks, the pigment included in the resin composition according to an embodiment of the present invention may include one kind of an organic pigment and on kind of an inorganic pigment in combination.

Particular examples of the pigment that may be used may include, as inorganic pigments, at least one selected from the group consisting of BaSO₄, ZnO, ZnS, fumed silica, talc, BiVO₄ (Pigment yellow 184), cobalt blue, iron red, carbon black, and TiO₂, and as organic pigments, at least one selected from the group consisting of pigment blue (2), pigment blue (15:3), pigment yellow (74), and pigment yellow (83), pigment yellow (139), pigment yellow (150). In addition, the pigment may be included in the resin composition using a dispersant such as Disperbyk111, Disperbyk9150, Disperbyk9151, Disperbyk2151, and Disperbyk 2152.

The ink jet resin composition according to an embodiment of the present invention may include 5 to 15 parts by weight of the thermosetting epoxy resin, 30 to 70 parts by weight of the monofunctional acrylate monomer, 5 to 50 parts by weight of the polyfunctional acrylate monomer, 5 to 15 parts by weight of the photoinitiator, and 1 to 10 parts by weight of the amine synergist.

By employing the thermosetting epoxy resin, the storage stability of the resin composition may be secured. In addition, by including the thermosetting epoxy resin in the above-described range in the resin composition, the adhesion of the resin composition to a substrate and a copper foil, or the improvement of the heat resistance of the cured resin layer may be secured.

In the case where the amount of the thermosetting epoxy resin is less than the above range, adhesion to a substrate, which is characteristic of the present composition, may not be attained and the amount is undesirable. In the case where the amount deviates from the above range, ink components such as a pigment may be separated in the composition, and the viscosity of the composition may increase, thereby decreasing storage stability, and the amount is undesirable.

In the case where the amount of the monofunctional acrylate is less than the above range, adhesion to a substrate may not be attained and the amount is undesirable. In the case where the amount is greater than the above range, ink components such as a pigment may be separated in the composition, curing density during curing may decrease, and the hardness of the coated film of an insulating resin layer may be insufficient, and thus, the amount is undesirable. In addition, the bifunctional acrylate monomer which may be included as a diluent in the resin composition may be included in an amount of 5 to 50 parts by weight based on 5 to 15 parts by weight of the epoxy resin.

If the amount of the polyfunctional acrylate is less than the above range, sometimes the solvent resistance with respect to a substrate and UV curing reactivity of the resin composition may not be obtained, and the amount is undesirable, and if the amount is greater than the above range, ink components such as a pigment may be separated in the composition, and adhesion may be deteriorated due to contraction (shrinkage) after a curing reaction, and thus, the amount is undesirable.

If the photoinitiator is included in an amount less than the above range, UV curing may be insufficiently performed, and if the amount is greater than the above range, reactivity during the thermal curing reaction of the resin composition may decrease.

If the amine synergist is included in an amount within the above range, the surface state of a finally formed cured resin layer may be poor, and if the amount of the amine synergist in the composition is greater than the above range, the reactivity of the thermal curing reaction may decrease.

The pigment may include the inorganic pigment and the organic pigment in a weight ratio of 5 to 10:1. If the pigment is included in the above range, the implementation of color (color stability) and hiding power may not be good, and if the amount is greater than the above range, UV curing reactivity and storing stability may not be good.

According to an embodiment of the present invention, in order to prevent the generation of polymerization during preparing a composition, 0.001 to 0.2 parts by weight of a polymerization inhibitor such as N-nitrophenyl hydroxylamine based on 5 to 15 parts by weight of the thermosetting epoxy resin, and 0.0001 to 1 parts by weight of a polymerization inhibitor such as 4-methoxyphenol (MEHQ) or butyrated hydroxyphenol (BHT) based on 5 to 15 parts by weight of the thermosetting epoxy resin may be further included, alone or as a mixture.

In addition, the resin composition according to an embodiment of the present invention may further include additives such as a well known polymerization inhibitor such as hydroquinone, hydroquinone monomethyl ether, tert-butylcatechol, pyrogallol and phenothiazine, a defoamer and/or leveling agent such as a silicon-based, fluorine-based, and polymer-based agent, and adhesion imparting agent such as an imidazole-based, thiazole-based and triazole-based adhesion imparting agent and a silane coupling agent.

After preparing the resin composition, an inspection process for inspecting the final viscosity, particle size, surface tension and specific gravity of the composition, and for inspecting a cured coating layer may be further included, and after conducting the inspection process, a filtering process may be further included in the preparation of the resin composition, in which the filtering of the resin composition may be performed using a filter for filtering particles having an average particle size greater than 1 μm.

According to another aspect of the present invention, there is provided a method of manufacturing a printed wiring board including discharging (jetting) the above-described resin composition as ink on one side or both sides of a substrate including a copper foil such as a PCB using an ink jet head, irradiating ultraviolet rays to the resin composition to form a resin layer on one side or both sides of the substrate, and heating the resin layer formed on one side or both sides of the substrate to form a cured resin layer.

In the case where the resin composition is coated on a substrate by a screen and spray method used in the conventional printed wiring board, after printing all over the substrate, a heating and drying process at 80° C. for about 30 to 60 minutes is required to remove a volatile organic solvent included in a resin layer formed after printing. In order to perform printing on both sides of the substrate, printing on a rear surface and then heating and drying again are required after the heating process, and an extended process time is necessary.

However, in the resin composition according to an embodiment of the present invention, in the case where ink is discharged (jetted), and ultraviolet rays are irradiated to form resin layers on one side or both sides of the substrate, surface stickiness may be minimized by using a non-volatile solvent and an epoxy resin when compared to the conventional case, discharging (jetting) and UV curing may be performed almost at the same time by using a photoinitiator and an amine synergist included in the resin composition, thereby easily forming resin layers on both sides of the substrate, a printing process may be performed on both sides without a separate heating and drying process, and an excellent printed wiring board may be manufactured without the deformation or spread of a resin layer even though thermal curing on both sides of a substrate is conducted at the same time.

### EXAMPLES

Hereinafter, embodiments on the ink jet resin composition according to an aspect of the present invention will be described and the present invention will be explained in particular. However, the present invention is not limited to the following embodiments. In addition, the term “parts” means parts by weight, unless specifically noted below.

### Examples 1-4 and Comparative Examples 1-4

Using the components and amounts listed in Tables 1 to 4, an epoxy resin was dissolved in a diluent to prepare Liquid 1, a pigment and a dispersant were dispersed in the diluent to prepare Liquid 2, a photoinitiator was dissolved in the diluent to prepare Liquid 3, and Liquids 1 to 3 and remaining components were mixed and stirred using a stirrer at a speed of 300 to 500 rpm at room temperature for 30 to 60 minutes to prepare each resin composition.

<Compounds>

Liquid BPA: a bisphenol A-type epoxy resin having an epoxy equivalent weight of 185 g/eq

Solid BPF: a bisphenol F-type epoxy resin having an epoxy equivalent weight of 500 g/eq

ECN: a cresol novolak epoxy resin having an epoxy equivalent weight of 220 g/eq

ACMO: acryolyl morpholine

CTFA: trimethylolpropane formal acrylate

IBOA: isobornyl acrylate

DPGDA: dipropylene glycol diacrylate

TMPTA: trimethylolpropane triacrylate

BAPO: bis(2,4,6-trimethylbenzoyl)-phenylphosphine oxide

DETX: 2,4-diethyl thioxanthone

DPHA: dipentaerythritol hexaacrylate

BHT: butyrated hydroxyphenol

NPHA: N-nitrophenyl hydroxylamine

Amine synergist: a compound of Formula 1

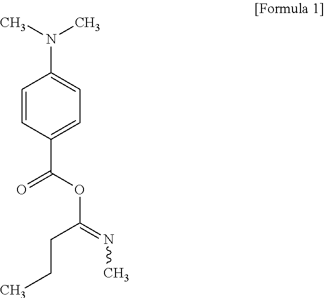

AS2010: manufactured by Miwon Commercial Co., Ltd.

DISPERBYK111: manufactured by BYK-Chemie GmbH Co., Ltd.

TABLE 1

| | | | Example 1 | | | | Example 2 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | Solid BPA | | | | | | | | |
| resin | | Liquid BPA | | | | | | | | |
| | | Solid BPF | | | | | | | | |
| | | ECN | 10 | 10 | | | 10 | 10 | | |
| Diluent | Monofunctional | ACMO | 20 | | | 20 | 20 | | | 20 |
| | | CTFA | 30 | 10 | 5 | 15 | 30 | 10 | 5 | 15 |
| | | IBOA | 10 | | | 10 | 10 | | | 10 |
| | Bifunctional | DPGDA | 25 | 10 | 5 | 10 | 25 | 10 | 5 | 10 |
| Viscosity | Trifunctional | TMPTA | 5 | | | | | | | |
| controlling | Tetrafunctional | Polyether | | | | | 5 | | | |
| agent | | tetraacrylate | | | | | | | | |

| | | | | | | | | | |
|---|---|---|---|---|---|---|---|---|---|
| Photoinitiator and photo | BAPO | 3 | | | 3 | 3 | | | 3 |
| auxiliary agent | DETX | 2 | | | 2 | 2 | | | 2 |
| Dispersant | DISPERBYK111 | 1 | | 1 | | 1 | | 1 | |
| Amine synergist | Formula 1 | 4 | | | | 4 | | | |
| Pigment | Pigment Yellow | 5 | | 5 | | 5 | | 5 | |
| | 184 | | | | | | | | |
| | Pigment Blue | 0.5 | | 0.5 | | 0.5 | | 0.5 | |
| | 15:3 | | | | | | | | |
| Thermal curing agent | Blocked | | | | | | | | |
| | isocyanate | | | | | | | | |
| Parts by weight | | 115.5 | 30 | 16.5 | 60 | 115.5 | 30 | 16.5 | 60 |

TABLE 2

| | | | Example 3 | | | | Example 4 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | Solid BPA | | | | | | | | |
| resin | | Liquid BPA | | | | | 10 | 10 | | |
| | | Solid BPF | 10 | 10 | | | | | | |
| | | ECN | | | | | | | | |
| Diluent | Monofunctional | ACMO | 20 | | | 20 | 20 | | | 20 |
| | | CTFA | 30 | 10 | 5 | 15 | 20 | | 5 | 15 |
| | | IBOA | 10 | | | 10 | 10 | | | 10 |
| | Bifunctional | DPGDA | 25 | 10 | 5 | 10 | 15 | | 5 | 10 |
| Viscosity | Trifunctional | TMPTA | | | | | | | | |
| controlling | Tetrafunctional | Polyether | 5 | | | | 5 | | | |
| agent | | tetraacrylate | | | | | | | | |

| | | | | | | | | | |
|---|---|---|---|---|---|---|---|---|---|
| Photoinitiator and photo | BAPO | 3 | | | 3 | 3 | | | 3 |
| auxiliary agent | DETX | 2 | | | 2 | 2 | | | 2 |
| Dispersant | DISPERBYK111 | 1 | | 1 | | 1 | | 1 | |
| Amine synergist | Formula 1 | 4 | | | | 4 | | | |
| Pigment | Pigment Yellow | 5 | | 5 | | 5 | | 5 | |
| | 184 | | | | | | | | |
| | Pigment Blue | 0.5 | | 0.5 | | 0.5 | | 0.5 | |
| | 15:3 | | | | | | | | |
| Thermal curing agent | Blocked | | | | | | | | |
| | isocyanate | | | | | | | | |
| | Parts by weight | 115.5 | 30 | 16.5 | 60 | 95.5 | 10 | 16.5 | 60 |

TABLE 3

| | | | Comparative Example 1 | | | | Comparative Example 2 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | Solid BPA | | | | | | | | |
| resin | | Liquid BPA | 10 | 10 | | | | | | |
| | | Solid BPF | | | | | 10 | 10 | | |
| | | ECN | | | | | | | | |
| Diluent | Monofunctional | ACMO | 20 | | | 20 | 20 | | | 20 |
| | | CTFA | 20 | | 5 | 15 | 30 | 10 | 5 | 15 |
| | | IBOA | 10 | | | 10 | 10 | | | 10 |
| | Bifunctional | DPGDA | 15 | | 5 | 10 | 25 | 10 | 5 | 10 |
| Viscosity | Trifunctional | TMPTA | 5 | | | | 5 | | | |
| controlling | Tetrafunctional | Polyether | | | | | | | | |
| agent | | tetraacrylate | | | | | | | | |

| | | | | | | | | | |
|---|---|---|---|---|---|---|---|---|---|
| Photoinitiator and photo | BAPO | 3 | | | 3 | 3 | | | 3 |
| auxiliary agent | DETX | 2 | | | 2 | 2 | | | 2 |
| Dispersant | DISPERBYK111 | 1 | | 1 | | 1 | | 1 | |
| Amine synergist | Formula 1 | 4 | | | | 4 | | | |
| Pigment | Pigment Yellow | 5 | | 5 | | 5 | | 5 | |
| | (184) | | | | | | | | |
| | Pigment Blue | 0.5 | | 0.5 | | 0.5 | | 0.5 | |
| | (15:3) | | | | | | | | |
| Thermal curing agent | Blocked | 1 | | | | 1 | | | |
| | isocyanate | | | | | | | | |
| Total | Parts by weight | 96.5 | 10 | 16.5 | 60 | 116.5 | 30 | 16.5 | 60 |

TABLE 4

| | | | Comparative Example 3 | | | | Comparative Example 4 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | Solid BPA | | | | | | | | |
| resin | | Liquid BPA | | | | | | | | |
| | | Solid BPF | | | | | | | | |
| | | ECN | 10 | 10 | | | 10 | 10 | | |
| Diluent | Monofunctional | ACMO | 20 | | | 20 | 20 | | | 20 |
| | | CTFA | 30 | 10 | 5 | 15 | 30 | 10 | 5 | 15 |
| | | IBOA | 10 | | | 10 | 10 | | | 10 |
| | Bifunctional | DPGDA | 25 | 10 | 5 | 10 | 25 | 10 | 5 | 15 |
| Viscosity | Trifunctional | TMPTA | 5 | | | | | | | |
| controlling | Tetrafunctional | Polyether | | | | | 5 | | | |
| agent | | tetraacrylate | | | | | | | | |

| Photoinitiator and photo | BAPO | 3 | | | 3 | 3 | | | 3 |
|---|---|---|---|---|---|---|---|---|---|
| auxiliary agent | DETX | 2 | | | 2 | 2 | | | 2 |
| Dispersant | DISPERBYK111 | 1 | | 1 | | 1 | | 1 | |
| Amine synergist | Formula 1 | 4 | | | | 4 | | | |
| Pigment | Pigment Yellow | 5 | | 5 | | 5 | | 5 | |
| | (184) | | | | | | | | |
| | Pigment Blue | 0.5 | | 0.5 | | 0.5 | | 0.5 | |
| | (15:3) | | | | | | | | |
| Thermal curing agent | Blocked | 1 | | | | 1 | | | |
| | isocyanate | | | | | | | | |
| Total | Parts by weight | 116.5 | 30 | 16.5 | 60 | 116.5 | 30 | 16.5 | 60 |

[Assessment]

Each of the resin compositions prepared in Examples 1 to 4 and Comparative Examples 1 to 4 was coated on a copper foil using an ink jet, exposed to light with a light intensity of 200 mJ/cm2 for pre-curing, and thermally cured at 150° C. for 60 minutes using a hot air circulation (convection)-type dryer to form a cured resin layer to obtain a sample for assessment.

(1) Surface State

The coated layer thus formed was observed with the naked eye, and the results were assessed with the numeral 5 when a smooth and uniform surface was formed and 1 when a sticky (uncured material) and liquid remaining surface was formed.

(2) Adhesion

With respect to a copper foil on which a cured resin layer was formed, adhesion between the copper foil and the resin layer was evaluated based on IPC-TM-650 2.4.1.6.

(3) Pencil Hardness

The pencil hardness of a cured resin layer of a sample for assessment was measured based on ASTM D3363.

TABLE 5

| | | | | | Comparative | Comparative | Comparative | Comparative |
|---|---|---|---|---|---|---|---|---|
| | Example 1 | Example 2 | Example 3 | Example 4 | Example 1 | Example 2 | Example 3 | Example 4 |
| Surface state | 5 | 5 | 5 | 5 | 5 | 5 | 5 | 5 |
| (200 mJ/cm²) | | | | | | | | |
| Adhesion | 5 | 5 | 5 | 5 | 1 | 2-3 | 5 | 5 |
| Pencil | 4H | 4H | 4H | 4H | H | 4H | 4H | 4H |
| hardness | | | | | | | | |

As shown in Table 5, the resin compositions according to example embodiments of the present invention were secured to have good properties of the overall surface state, the adhesion and the pencil hardness.

### Comparative Examples 5-10

Resin compositions were prepared by the same method described in Example 1 with the components and amounts illustrated in Tables 6 and 7.

TABLE 6

| | | | Comparative Example 5 | | | | Comparative Example 6 | | | | Comparative Example 7 | | | |
|---|---|---|---|---|---|---|---|---|---|---|---|---|---|---|
| | | | | Liq- | Liq- | Liq- | | Liq- | Liq- | Liq- | | Liq- | Liq- | Liq- |
| Component | | | Total | uid 1 | uid 2 | uid 3 | Total | uid 1 | uid 2 | uid 3 | Total | uid 1 | uid 2 | uid 3 |
| Thermosetting | Epoxy resin | ECN | 5 | 5 | | | 10 | 10 | | | 10 | 10 | | |
| resin | | | | | | | | | | | | | | |
| Diluent | Monofunctional | ACMO | 20 | | | 20 | 20 | | | 20 | 20 | | | 20 |
| | | CTFA | 25 | 5 | 5 | 15 | 30 | 10 | 5 | 15 | 30 | 10 | 5 | 15 |
| | | IBOA | 10 | | | 10 | 10 | | | 10 | 10 | | | 10 |
| | Bifunctional | DPGDA | 20 | 5 | 5 | 10 | 25 | 10 | 5 | 10 | 25 | 10 | 5 | 10 |
| Viscosity | Tetrafunctional | Polyether | 5 | | | | 5 | | | | 5 | | | |
| controlling | | tetraacrylate | | | | | | | | | | | | |
| agent | | | | | | | | | | | | | | |

| | | | | | | | | | | | | | |
|---|---|---|---|---|---|---|---|---|---|---|---|---|---|
| Photoinitiator and photo | BAPO | 3 | | | 3 | 1.5 | | | 1.5 | 6 | | | 6 |
| auxiliary agent | DETX | 2 | | | 2 | 1 | | | 1 | 4 | | | 4 |
| Dispersant | DISPERBYK111 | 1 | | 1 | | 1 | | 1 | | 1 | | 1 | |
| Amine synergist | Formula 1 | 4 | | | | 2 | | | | 8 | | | |
| Pigment | Pigment Yellow | 5 | | 5 | | 5 | | 5 | | 5 | | 5 | |
| | (184) | | | | | | | | | | | | |
| | Pigment Blue | 0.5 | | 0.5 | | 0.5 | | 0.5 | | 0.5 | | 0.5 | |
| | (15:3) | | | | | | | | | | | | |
| | Parts by weight | 100.5 | 15 | 16.5 | 60 | 111 | 30 | 16.5 | 57.5 | 124.5 | 30 | 16.5 | 65 |

TABLE 7

| | | | Comparative Example 8 | | | | Comparative Example 9 | | | | Comparative Example 10 | | | |
|---|---|---|---|---|---|---|---|---|---|---|---|---|---|---|
| | | | | Liq- | Liq- | Liq- | | Liq- | Liq- | Liq- | | Liq- | Liq- | Liq- |
| Compontent | | | Total | uid 1 | uid 2 | uid 3 | Total | uid 1 | uid 2 | uid 3 | Total | uid 1 | uid 2 | uid 3 |
| Thermosetting | Epoxy resin | ECN | 10 | 10 | | | 10 | 10 | | | 10 | 10 | | |
| resin | | | | | | | | | | | | | | |
| Diluent | Monofunctional | ACMO | 20 | | | 20 | 20 | | | 20 | 20 | | | 20 |
| | | CTFA | 30 | 10 | 5 | 15 | 30 | 10 | 5 | 15 | 30 | 10 | 5 | 15 |
| | | IBOA | 10 | | | 10 | 10 | | | 10 | 10 | | | 10 |
| | Bifunctional | DPGDA | 25 | 10 | 5 | 10 | 25 | 10 | 5 | 10 | 25 | 10 | 5 | 10 |
| Viscosity | Tetrafunctional | Polyether | 5 | | | | 5 | | | | 5 | | | |
| controlling | | tetraacrylate | | | | | | | | | | | | |
| agent | | | | | | | | | | | | | | |

| Photoinitiator and photo | BAPO | 3 | | | 3 | 3 | | | 3 | 3 | | | 3 |
|---|---|---|---|---|---|---|---|---|---|---|---|---|---|
| auxiliary agent | DETX | 2 | | | 2 | 2 | | | 2 | 2 | | | 2 |
| Dispersant | DISPERBYK111 | 1 | | 1 | | 1 | | 1 | | 1 | | 1 | |
| Amine synergist | Formula 1 | 2 | | | | 8 | | | | | | | |
| Pigment | Pigment Yellow | 5 | | 5 | | 5 | | 5 | | 5 | | 5 | |
| | (184) | | | | | | | | | | | | |
| | Pigment Blue | 0.5 | | 0.5 | | 0.5 | | 0.5 | | 0.5 | | 0.5 | |
| | (15:3) | | | | | | | | | | | | |
| | Parts by weight | 113.5 | 30 | 16.5 | 60 | 119.5 | 30 | 16.5 | 60 | 111.5 | 30 | 16.5 | 60 |

[Assessment]

Each of the resin compositions prepared in Example 2 and Comparative Examples 5 to 10 was coated on a copper foil using an ink jet, and exposed to light for pre-curing with the irradiation conditions of a lamp of low intensity or high intensity as illustrated in the following Table 8 while being moved on a conveyor belt, and thermally cured at 150° C. for 60 minutes using a hot air circulation (convection)-type dryer to form a cured resin layer to obtain a sample for assessment. In this case, the intensity conditions are shown in Table 8 below.

TABLE 8

| | Conveyor | | | | |
|---|---|---|---|---|---|
| | belt speed | UVA | UVB | UVA2 | UVV |
| | (Meter/min) | (mJ/cm²) | (mJ/cm²) | (mJ/cm²) | (mJ/cm²) |
| Low | 1 | 722 | 444 | 148 | 667 |
| intensity | 3 | 216 | 137 | 42 | 197 |
| | 5 | 127 | 80 | 24 | 115 |
| | 6 | 103 | 65 | 20 | 94 |
| | 7 | 88 | 56 | 17 | 79 |
| | 8.8 (MAX) | 65 | 42 | 12 | 59 |
| High | 1 | 1810 | 820 | 720 | 1851 |
| intensity | 3 | 577 | 262 | 226 | 583 |
| | 5 | 326 | 150 | 127 | 329 |
| | 6 | 271 | 124 | 106 | 274 |
| | 7 | 226 | 105 | 88 | 229 |
| | 8.8 (MAX) | 169 | 80 | 65 | 171 |

(UV Intensity → Half)

(1) Surface State

The coated layer thus formed was observed with the naked eye, and the results were assessed with the numeral 5 when a smooth and uniform surface was formed and 1 when a sticky (uncured material) and liquid remaining surface was formed.

(2) Adhesion

With respect to a copper foil on which a cured resin layer was formed, adhesion between the copper foil and the resin layer was evaluated based on IPC-TM-650 2.4.1.6.

(3) Pencil Hardness

The pencil hardness of a cured resin layer of a sample for assessment was measured based on ASTM D3363.

(4) Heat Resistance

After leaving a sample for assessment at 288° C. for seconds, the sample was cooled to room temperature. This process was repeated three times. The deformation of the cured resin layer which was formed on the sample for assessment was observed with the naked eye for each repetition, and the results were assessed as ◯ when no deformation (Crack or delamination) occurred, and X when deformation occurred.

(5) Assessment on Adhesion after Assessing Heat Resistance

The adhesion of the sample for assessment after measuring the heat resistance according to the above (4) was evaluated. The results were assessed as 5 when the adhesion was the best and 1 when the adhesion was poor.

TABLE 9

| | | | Comparative | Comparative | Comparative | Comparative | Comparative | Comparative |
|---|---|---|---|---|---|---|---|---|
| | | Example 2 | Example 5 | Example 6 | Example 7 | Example 8 | Example 9 | Example 10 |
| Surface | Low | 5 | 5 | 4 | 5 | 4 | 5 | 3 |
| state | intensity | | | | | | | |
| | High | 5 | 5 | 4 | 5 | 5 | 5 | 3 |
| | intensity | | | | | | | |
| Adhesion | Low | 5 | 4 | 5 | 4 | 5 | 5 | 5 |
| | intensity | | | | | | | |
| | High | 5 | 5 | 5 | 4 | 5 | 4 | 5 |
| | intensity | | | | | | | |
| Pencil | Low | 4H | 4H | 4H | 3H | 4H | 4H | 4H |
| hardness | intensity | | | | | | | |
| | High | 4H | 4H | 4H | 3H | 4H | 4H | 4H |
| | intensity | | | | | | | |
| Heat | Low | Three | Three | Twice ◯ | Three | Three | Three | Three |
| resistance | intensity | times ◯ | times ◯ | Three | times ◯ | times ◯ | times ◯ | times ◯ |
| | | | | times X | | | | |
| | High | Three | Three | Twice ◯ | Three | Three | Once ◯ | Three |
| | intensity | times ◯ | times ◯ | Three | times ◯ | times ◯ | Twice X | times ◯ |
| | | | | times X | | | Three | |
| | | | | | | | times X | |
| Adhesion | Low | 5 | 1 | 5 | 4.5 | 5 | 4.5 | 5 |
| after heat | intensity | | | | | | | |
| resistance | High | 5 | 4 | 5 | 4 | 5 | 4 | 5 |
| evaluation | intensity | | | | | | | |

As shown above, it was confirmed that only the resin composition of Example 2 satisfied all physical properties at the low intensity and the high intensity. In particular, for the resin composition of Comparative Example 5 in which the epoxy content was decreased, the adhesion was deteriorated, and for the resin composition of Comparative Example 6 in which the photoinitiator content was low, the surface state was deteriorated. In addition, as in Comparative Examples 8, 9 and 10, the surface state and the heat resistance were decreased in accordance with the amine synergist content.

### Example 5 and Comparative Example 11

Resin compositions were prepared by the same method described in Example 1 and using the components and amounts illustrated in Table 10. In Comparative Example 11, the pigment was a combination of two kinds of organic pigments, Pigment yellow 150 and Pigment Blue (15:3).

TABLE 10

| | | | Example 5 | | | | Comparative Example 11 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | ECN | 10 | 10 | | | 5 | 5 | | |
| resin | | | | | | | | | | |
| Diluent | Monofunctional | ACMO | 20 | | | 20 | 20 | | | 20 |
| | | CTFA | 30 | 10 | 5 | 15 | 25 | 5 | 5 | 15 |
| | | IBOA | 10 | | | 10 | 10 | | | 10 |
| | Bifunctional | DPGDA | 25 | 10 | 5 | 10 | 20 | 5 | 5 | 10 |
| Viscosity | Tetrafunctional | Polyether | 5 | | | | 5 | | | |
| controlling | | tetraacrylate | | | | | | | | |
| agent | | | | | | | | | | |

| Photoinitiator and photo | BAPO | 3 | | | 3 | 3 | | | 3 |
|---|---|---|---|---|---|---|---|---|---|
| auxiliary agent | DETX | 2 | | | 2 | 2 | | | 2 |
| | DISPERBYK111 | 1 | | 1 | | 1 | | 1 | |
| Amine synergist | Formula 1 | 4 | | | | 4 | | | |
| Pigment | Pigment Yellow | 5 | | 5 | | | | | |
| | (184) | | | | | | | | |
| | Pigment Yellow | | | | | 0.5 | | 0.5 | |
| | (150) | | | | | | | | |
| | Pigment Blue | 0.5 | | 0.5 | | 0.5 | | 0.5 | |
| | (15:3) | | | | | | | | |
| | Parts by weight | 115.5 | 30 | 16.5 | 60 | 96 | 15 | 11.5 | 60 |

[Assessment]

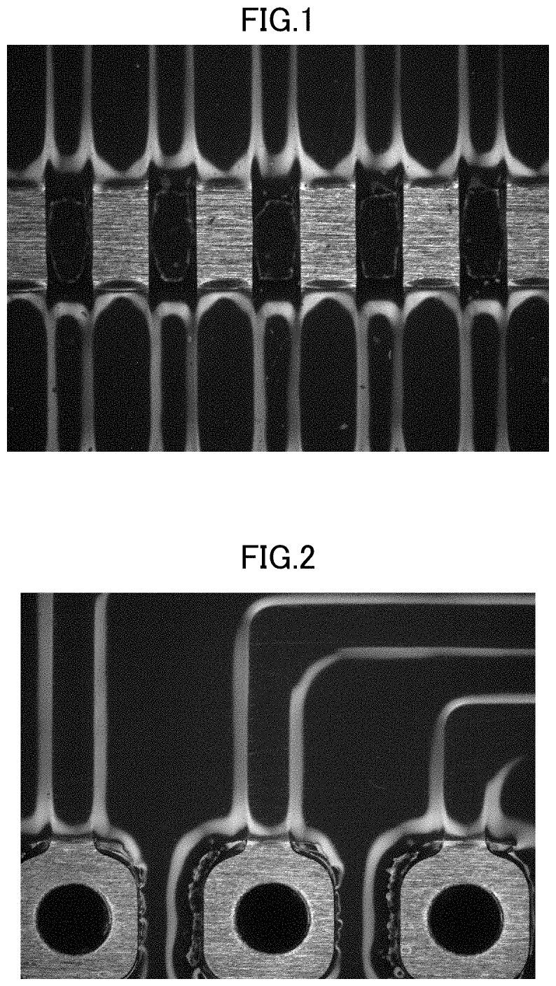

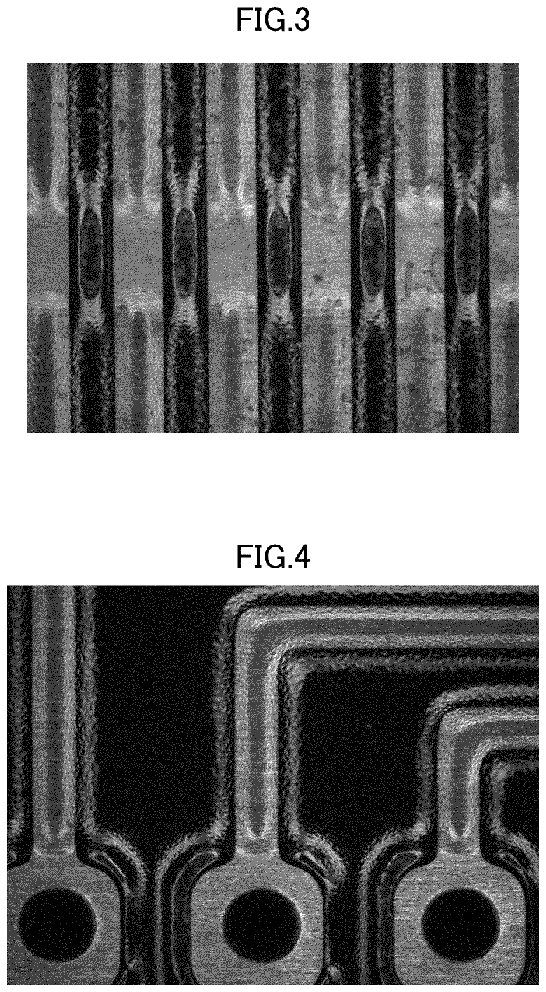

Each of the resin compositions prepared in Example and Comparative Example 11 was coated on a substrate (PCB) on which a copper foil was formed using an ink jet, exposed to light with a light intensity of 200 mJ/cm² to pre-cure, and thermally cured at 150° C. for 60 minutes using a hot air circulation (convection)-type dryer to form a cured resin layer to obtain a sample for assessment. Then, the surface pictures of the sample were taken, and the results are shown in FIGS. 1 and 2 for the surface of Example 2, and FIGS. 3 and 4 for the surface of Comparative Example 11.

When a combination of only organic pigments was used, hiding power was deteriorated, and the scratches of a copper foil on a base substrate were seen therethrough as shown in FIG. 3, but when a combination of an organic pigment and an inorganic pigment was used according to an embodiment of the present invention, the scratches of a copper foil on a base substrate were not seen, and a good surface state was secured.

### Examples 6-8 and Comparative Examples 12-13

Resin compositions were prepared by the same method described in Example 1 and using the components and amounts illustrated in Tables 11 to 13.

TABLE 11

| | | | Example 6 | | | | Example 7 | | | |
|---|---|---|---|---|---|---|---|---|---|---|
| Component | | | Total | Liquid 1 | Liquid 2 | Liquid 3 | Total | Liquid 1 | Liquid 2 | Liquid 3 |
| Thermosetting | Epoxy resin | ECN | 10 | 10 | | | 5 | 5 | | |
| resin | | | | | | | | | | |
| Diluent | Monofunctional | ACMO | 20 | | | 20 | 20 | | | 20 |
| | | CTFA | 30 | 10 | 5 | 15 | 25 | 5 | 5 | 15 |
| | | IBOA | 10 | | | 10 | 10 | | | 10 |
| | Bifunctional | DPGDA | 25 | 10 | 5 | 10 | 20 | 5 | 5 | 10 |
| Viscosity | Tetrafunctional | Polyether | 3 | | | | 3 | | | |
| controlling | | tetraacrylate | | | | | | | | |
| agent | Hexafunctional | DPHA | 3 | | | | 3 | | | |

| Photoinitiator and photo | BAPO | 3 | | | 3 | 3 | | | 3 |
|---|---|---|---|---|---|---|---|---|---|
| auxiliary agent | DETX | 2 | | | 2 | 2 | | | 2 |
| Dispersant | DISPERBYK111 | 1 | | 1 | | 1 | | 1 | |
| Amine synergist | Formula 1 | 5 | | | | 5 | | | |
| Pigment | Pigment Yellow | 5 | | 5 | | 5 | | 5 | |
| | (184) | | | | | | | | |
| | Pigment Blue | 0.5 | | 0.5 | | 0.5 | | 0.5 | |
| | (15:3) | | | | | | | | |
| Polymerization | NPHA | 0.001 | 0.001 | | | 0.001 | 0.001 | | |
| inhibitor | BHT | 0.501 | | 0.001 | 0.5 | 0.501 | | 0.001 | 0.5 |
| | Parts by weight | 118.002 | 30.001 | 16.501 | 60.5 | 103.002 | 15.001 | 16.501 | 60.5 |

TABLE 12

| | | | | | | | Comparative | | | |
|---|---|---|---|---|---|---|---|---|---|---|
| | | | Example 8 | | | | Example 12 | | | |
| Component | | | Total | Liquid 1 | Liquid 2 | Liquid 3 | Total | Liquid 1 | Liquid 2 | Liquid 3 |
| Thermosetting | Epoxy resin | ECN | 10 | 10 | | | 3.3 | 3.3 | | |
| resin | | | | | | | | | | |
| Diluent | Monofunctional | ACMO | 20 | | | 20 | 20 | | | 20 |
| | | CTFA | 30 | 10 | 5 | 15 | 23.4 | 3.4 | 5 | 15 |
| | | IBOA | 10 | | | 10 | 10 | | | 10 |
| | Bifunctional | DPGDA | 25 | 10 | 5 | 10 | 18.3 | 3.3 | 5 | 10 |
| Viscosity | Tetrafunctional | Polyether | 3 | | | | 3 | | | |
| controlling | | tetraacrylate | | | | | | | | |
| agent | Hexafunctional | DPHA | 3 | | | | 3 | | | |

| Photoinitiator and photo | BAPO | 3 | | | 3 | 3 | | | 3 |
|---|---|---|---|---|---|---|---|---|---|
| auxiliary agent | DETX | 2 | | | 2 | 2 | | | 2 |
| Dispersant | DISPERBYK111 | 1 | | 1 | | | | 1 | |
| Amine synergist | Formula 1 | | | | | 5 | | | |
| | AS2010 | 5 | | | | | | | |
| | (liquid phase) | | | | | | | | |
| Pigment | Pigment Yellow | 5 | | 5 | | 5 | | 5 | |
| | (184) | | | | | | | | |
| | Pigment Blue | 0.5 | | 0.5 | | 0.5 | | 0.5 | |
| | (15:3) | | | | | | | | |
| Polymerization | NPHA | 0.001 | | | | 0.001 | 0.001 | | |
| inhibitor | BHT | 0.501 | | 0.001 | 0.501 | 0.501 | | 0.001 | 0.5 |
| | Parts by weight | 118.002 | 30.001 | 16.501 | 60.5 | 97.002 | 10.001 | 16.501 | 60.5 |

TABLE 13

| | | | Comparative Example 13 | | | |
|---|---|---|---|---|---|---|
| Component | | | Total | Liquid 1 | Liquid 2 | Liquid 3 |
| Thermosetting | Epoxy resin | ECN | 20 | 20 | | |
| resin | | | | | | |
| Diluent | Monofunctional | ACMO | 20 | | | 20 |
| | | CTFA | 30 | 10 | 5 | 15 |
| | | IBOA | 10 | | | 10 |
| | Bifunctional | DPGDA | 25 | 10 | 5 | 10 |
| Viscosity | Tetrafunctional | Polyether | 3 | | | |
| controlling | | tetraacrylate | | | | |
| agent | Hexafunctional | DPHA | 3 | | | |

| | | | | | |
|---|---|---|---|---|---|
| Photoinitiator and photo | BAPO | 3 | | | 3 |
| auxiliary agent | DETX | 2 | | | 2 |
| Dispersant | DISPERBYK111 | 1 | | 1 | |
| Amine synergist | Formula 1 | 5 | | | |
| Pigment | Pigment Yellow | 5 | | 5 | |
| | (184) | | | | |
| | Pigment Blue | 0.5 | | 0.5 | |
| | (15:3) | | | | |
| Polymerization inhibitor | NPHA | 0.001 | 0.001 | | |
| | BHT | 0.501 | | 0.001 | 0.5 |
| | Parts by weight | 128.002 | 40.001 | 16.501 | 60.5 |

[Assessment]

Each of the resin compositions prepared in Examples 6 to 8 and Comparative Examples 12 to 13 was coated on a copper foil using an ink jet, exposed to light with a light intensity of 150 mJ/cm² at 385 nm using an LED lamp for pre-curing, and thermally cured at 150° C. for 60 minutes using a hot air circulation (convection)-type dryer to form a cured resin layer to obtain a sample for assessment.

(1) Adhesion

With respect to a copper foil on which a cured resin layer was formed, adhesion between the copper foil and the resin layer was evaluated based on IPC-TM-650 2.4.1.6.

(2) Pencil Hardness

The pencil hardness of a cured resin layer of a sample for assessment was measured based on ASTM D3363.

(3) Heat Resistance

After leaving a sample for assessment at 288° C. for seconds, the sample was cooled to room temperature. This process was repeated three times. The deformation of the cured resin layer formed on the sample for assessment was observed with the naked eye for each repetition, and the results were assessed as ◯ when no deformation (Crack or delamination) occurred, and X when deformation occurred.

(4) Solvent Resistance

A piece of cloth was wet with propylene glycol monomethyl ether acetate, and a cured resin layer was repeatedly rubbed with the cloth ten times. A case where the cloth was stained with the dissolved portion of the cured resin layer was regarded as poor.

(5) Plating Resistance

Experiments on electroless nickel/immersion gold plating (ENIG) properties on the cured resin layers thus manufactured in the examples and the comparative examples were conducted, and liquid permeation or exfoliation after the electroless nickel/immersion gold plating was observed with the naked eye. As a result, after the electroless nickel/immersion gold plating, a case where no liquid permeation or exfoliation (expansion or delamination) was observed with the naked eye was regarded as “OK”, and a case where liquid permeation or exfoliation (expansion or delamination) was observed with the naked eye was regarded as “NG”.

TABLE 14

| | | | | Comparative | Comparative |
|---|---|---|---|---|---|
| | Example 6 | Example 7 | Example 8 | Example 12 | Example 13 |
| UV curability | OK | OK | OK | OK | * Unmeasurable: |
| (150 mJ/cm²) | | | | | has high |
| | | | | | viscosity, and is |
| | | | | | not discharged |
| | | | | | (jetted) from ink |
| | | | | | jet head |
| Adhesion | 5 | 5 | 5 | 5 | |
| Pencil hardness | 5H | 5H | 5H | 5H | |
| Heat resistance | Three | Three | Three | Three | |
| | times pass | times pass | times pass | times pass | |
| Solvent resistance | Pass | Pass | Pass | Pass | |
| Plating resistance | OK | OK | OK | NG | |

As shown in the above table, the resin compositions which deviate from the content range of the thermosetting resin of the present disclosure according to Comparative Examples 12 and 13 were found to be difficult in securing desired physical properties of a resin composition.

1. An ink jet resin composition, comprising a thermosetting epoxy resin, a monofunctional acrylate monomer, a polyfunctional acrylate monomer, a photoinitiator, and an amine synergist.

2. The ink jet resin composition of claim 1, wherein the resin composition further comprises a pigment.

3. The ink jet composition of claim 1, wherein the epoxy resin has an epoxy equivalent weight (EEW) of 200 g/eq to 600 g/eq.

4. The ink jet resin composition of claim 1, wherein the epoxy resin has a weight average molecular weight of 1,000 to 5,000.

5. The ink jet resin composition of claim 1, wherein the epoxy resin comprises at least one selected from the group consisting of a bisphenol A-type epoxy resin, a bisphenol F-type epoxy resin, a cresol novolak epoxy resin, a phenol novolak epoxy resin, halogen substituted products of the above resins, alkynol substituted products of the above resins, and hydrogenation products of the above resins.

6. The ink jet resin composition of claim 1, wherein the monofunctional acrylate monomer comprises at least one selected from the group consisting of isobornyl acrylate (IBOA), acryloyl morpholine (ACMO), trimethylolpropane formal acrylate (CTFA), and 2-phenoxyethyl acrylate (2PEA).

7. The ink jet resin composition of claim 1, wherein the polyfunctional acrylate monomer comprises at least one selected from the group consisting of dipentaerythritol hexaacrylate (DPHA), pentaerythritol triacrylate (PETA), pentaerythritol tetraacrylate (PETRA), ditrimethylolpropane tetraacrylate (DiTMPTA), polyether tetraacrylate, polyester tetraacrylate, trimethylolpropane triacrylate (TMPTA), and tricyclodecane dimethanol diacrylate (TCDDA).

8. The ink jet resin composition of claim 1, wherein the photoinitiator comprises at least one selected from the group consisting of an α-hydroxyketone-based compound, a benzyldimethyl-ketal-based compound, an α-aminoketone-based compound, a bis-acyl phosphine-based (BAPO) compound, and a mono acyl phosphine-based compound.

9. The ink jet resin composition of claim 1, wherein the resin composition further comprises a photo auxiliary agent (Photosensitizer), and the photo auxiliary agent comprises at least one of a phosphine oxide-based compound or a thioxanthone-based compound.

10. The ink jet resin composition of claim 1, wherein the amine synergist is an acrylate comprising two to five tertiary amine structures in a molecule.

11. The ink jet resin composition of claim 10, wherein the amine synergist comprises at least one selected from the group consisting of a compound represented by the following Formula 1, bis-N,N-[(4-dimethylaminobenzoyl)oxiethylen-1-yl]-methylamine, MIRAMER AS2010 (Miwon Commercial Co., Ltd.), and MIRAMER AS5142 (Miwon Commercial Co., Ltd.) or derivative thereof:

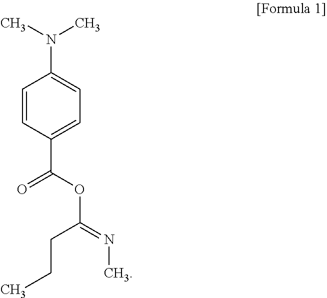 [SMILES: CCC/C(=N\C)OC(=O)c1ccc(N(C)C)cc1]

12. The ink jet resin composition of claim 2, wherein the pigment comprises an inorganic pigment and an organic pigment in a weight ratio of 8 to 10:1.

13. The ink jet resin composition of claim 1, wherein the resin composition further comprises at least one of dipropylene glycol diacrylate (DPGDA) or 1,6-hexanediol diacrylate (HDDA) as a bifunctional acrylate monomer.

14. The ink jet resin composition of claim 1, wherein the resin composition comprises 5 to 15 parts by weight of the thermosetting epoxy resin, 30 to 70 parts by weight of the monofunctional acrylate monomer, 5 to 50 parts by weight of the polyfunctional acrylate monomer, 5 to 15 parts by weight of the photoinitiator, and 1 to 10 parts by weight of the amine synergist.

15. The ink jet resin composition of claim 2, wherein the pigment is comprised in the resin composition in a weight ratio of 1 to 10 parts by weight.

16. A method of manufacturing a printed wiring board, the method comprising:
discharging (jetting) the resin composition described in claim 1 as ink using an ink jet head on one side or both sides of a substrate comprising a copper foil;
irradiating ultraviolet rays to the resin composition to form a resin layer on one side or both sides of the substrate; and
heating the resin layer formed on one side or both sides of the substrate to form a cured resin layer.
